(19) United States
(12) Patent Application Publication
(10) Pub. No.: US 2021/0335964 A1
(43) Pub. Date: Oct. 28, 2021

(54) ORGANIC LIGHT-EMITTING DISPLAY PANEL AND MANUFACTURING METHOD THEREOF

(71) Applicant: SHENZHEN CHINA STAR OPTOELECTRONICS SEMICONDUCTOR DISPLAY TECHNOLOGY CO., LTD., Shenzhen (CN)

(72) Inventors: Zhenguo LIN, Shenzhen (CN); Xingyu ZHOU, Shenzhen (CN); Yuanjun HSU, Shenzhen (CN); Poyen LU, Shenzhen (CN)

(73) Assignee: SHENZHEN CHINA STAR OPTOELECTRONICS SEMICONDUCTOR DISPLAY TECHNOLOGY CO., LTD, Shenzhen (CN)

(21) Appl. No.: 16/616,986

(22) PCT Filed: Oct. 12, 2019
(86) PCT No.: PCT/CN2019/110697

§ 371 Date: Nov. 26, 2019

(30) Foreign Application Priority Data
Aug. 22, 2019 (CN) 201910780428.5

(51) Int. Cl. H01L 27/32; H01L 51/56; H01L 51/52

(52) U.S. Cl. CPC H01L 27/3272; H01L 27/3246; H01L 51/56; H01L 2251/308; H01L 27/3265; H01L 51/5212; H01L 2227/323; H01L 27/3262

(57) ABSTRACT

The present disclosure provides an organic light-emitting display panel and a manufacturing method thereof. The organic light-emitting display panel includes: a substrate, a first electrode, a light-shielding layer, a buffer layer, and a second electrode. The technical effect of the present disclosure is that: the first electrode adopts a composition, such as transparent indium-doped zinc oxide (IZO) and indium gallium zinc oxide (IGZO), and the transparent first electrode can be disposed on a bottom of a light-emitting area to reduce sizes of pixel areas and improve resolution of organic light-emitting display panels.

### FIELD OF INVENTION

The present disclosure relates to the field of display technologies, and more particularly to an organic light-emitting display panel and a manufacturing method thereof.

### BACKGROUND OF INVENTION

With development of display panel industries, large size and high resolution display panels have become a mainstream. However, one of the main problems in large size and high resolution display panels is that size of pixel area is too large, leading to insufficient resolution of display panels.

As shown in FIG. 1, a current display panel is divided into a thin film transistor area 110, a light-emitting area 120, and a capacitor area 130. A first capacitor layer 140 is disposed between a buffer layer and an insulating layer of the capacitor area 130, a second capacitor layer 150 is disposed between the insulating layer and a passivation layer of the capacitor area 130, and the second capacitor layer 150 is disposed opposite to the first capacitor layer 140.

Lengths of the light-emitting area 120 and the capacitor area 130 are greater. In order to reduce the size of the pixel area, sizes of the thin film transistor area, the capacitor area, and the light-emitting area need to be reduced. However, in order to ensure capacitors and thin film transistors having a predetermined size, a range for size reduction is limited.

Technical problem: an objective of the present disclosure is to solve the technical problem of a larger size of the pixel area and a smaller size of the light-emitting area in current technology.

### SUMMARY OF INVENTION

To achieve the above object, the present disclosure provides an organic light-emitting display panel which comprises: a substrate comprising a thin film transistor and a light-emitting area; a first electrode disposed on the substrate, wherein the first electrode is a transparent electrode; a light-shielding layer disposed on the first electrode; a buffer layer disposed on the light-shielding layer; and a second electrode disposed on the buffer layer, wherein the second electrode is a transparent electrode; wherein the first electrode and the second electrode form a transparent capacitor in the light-emitting area.

Further, material of the first electrode comprises at least one of transparent indium-doped zinc oxide, aluminum-doped zinc oxide, or aluminum-indium-doped zinc oxide.

Further, material of the second electrode comprises at least one of indium gallium zinc oxide, indium zinc titanium oxide, or indium gallium zinc titanium oxide.

Further, the first electrode extends from below the second electrode of the light-emitting area to below the light-shielding layer.

Further, the thin film transistor comprises: an active layer disposed on the buffer layer; a gate insulating layer disposed on the active layer; a gate electrode disposed on the gate insulating layer; a dielectric layer disposed on the gate electrode; a first through-hole penetrating through the dielectric layer; and a source/drain electrode layer disposed on the dielectric layer and electrically connected to the active layer by the first through-hole.

Further, the organic light-emitting display panel further comprises: a passivation layer disposed on the dielectric layer; a planar layer disposed on the passivation layer; a second through-hole recessed in the planar layer and part of the passivation layer; an anode layer disposed on an inner side wall of the second through-hole and extending to the planar layer of the light-emitting area; a pixel definition layer disposed on the planar layer and the anode layer; and a third through-hole penetrating through the pixel definition layer.

Further, the organic light-emitting display panel further comprises: a color resist layer disposed on the passivation layer of the light-emitting area and opposite to the third through-hole; wherein the planar layer is disposed on the passivation layer and the color resist layer.

Further, the second electrode is disposed opposite to the third through-hole.

To achieve the above object, the present disclosure further provides a manufacturing method of an organic light-emitting display panel.

The method comprises: providing a substrate; preparing a first electrode and a light-shielding layer on an upper surface of the substrate; preparing a buffer layer on upper surfaces of the substrate, the first electrode, and the light-shielding layer; and preparing a thin film transistor and a second electrode on an upper surface of the buffer layer, wherein the thin film transistor is disposed on the second electrode making the first electrode and the second electrode form a transparent capacitor in the light-emitting area.

Further, the preparing step of the first electrode comprises: coating a first electrode material on the upper surface of the substrate; coating a light-shielding material on an upper surface of the first electrode material; coating a layer of photoresist on an upper surface of the light-shielding material; and etching to form the first electrode and the light-shielding layer; the preparing step of the second electrode comprises: preparing a semiconductor layer on the upper surface of the buffer layer and etching to form a semiconductor pattern; preparing a gate insulating layer on an upper surface of the semiconductor pattern; preparing a gate electrode layer on an upper surface of the gate insulating layer; etching a pattern of the gate electrode layer first, then etching a pattern of the gate insulating layer, and making the pattern of the gate insulating layer disposed opposite to the pattern of the gate electrode layer; performing a plasma treatment on the entire upper surface of the substrate that makes the semiconductor pattern not covered by the gate insulating layer form a conductor layer and the semiconductor pattern covered by the gate insulating layer form thin film transistor channels; and conductorizing the conductor layer on the light-emitting area to form the second electrode.

The technical effect of the present disclosure is: removing the original first capacitor layer in the pixel area and disposing a new first electrode on a bottom of the display panel. Material of the first electrode comprises at least one of transparent indium-doped zinc oxide (IZO), aluminum-doped zinc oxide (AZO), or aluminum-indium-doped zinc oxide (IAZO). The above oxides have good volatility that prevents material residue during etching and improves etching effect. The present disclosure disposes capacitors which are originally in the original capacitor area in the light-emitting area, and removes the original capacitor area to reduce sizes of pixel areas, thereby improving resolution of display panels.

### DESCRIPTION OF DRAWINGS

FIG. 1 is a schematic structural diagram of a display panel in current technology.

FIG. 2 is a schematic structural diagram of an organic light-emitting display panel according to an embodiment of the present disclosure.

FIG. 3 is a schematic structural diagram of another organic light-emitting display panel according to an embodiment of the present disclosure.

FIG. 4 is a flowchart of a manufacturing method of an organic light-emitting display panel according to an embodiment of the present disclosure.

FIG. 5 is a flowchart of a preparing step of the first electrode according to an embodiment of the present disclosure.

FIG. 6 is a schematic structural diagram of an organic light-emitting display panel before an etching step according to an embodiment of the present disclosure.

FIG. 7 is a schematic structural diagram of an organic light-emitting display panel after a first time etching the light-shielding layer according to an embodiment of the present disclosure.

FIG. 8 is a schematic structural diagram of an organic light-emitting display panel after etching the first electrode according to an embodiment of the present disclosure.

FIG. 9 is a schematic structural diagram of an organic light-emitting display panel after treatment of the photoresist according to an embodiment of the present disclosure.

FIG. 10 is a schematic structural diagram of an organic light-emitting display panel after a second time etching the light-shielding layer according to an embodiment of the present disclosure.

FIG. 11 is a flowchart of a preparing step of the second electrode according to an embodiment of the present disclosure.

### DETAILED DESCRIPTION OF PREFERRED EMBODIMENTS

The preferred embodiments of the present disclosure are described in detail below with reference to the accompanying drawings. The specific embodiments described with reference to the attached drawings are all exemplary and are intended to illustrate and interpret the present disclosure to make the skilled in the art easier to understand how to implement the present disclosure. The disclosure herein provides many different embodiments or examples for realizing different structures of the present disclosure. They are only examples and are not intended to limit the present disclosure.

In the description of the present disclosure, it should be understood that terms such as “upper”, “lower”, “front”, “rear”, “left”, “right”, “inside”, “outside”, “side”, as well as derivative thereof should be construed to refer to the orientation as described or as shown in the drawings under discussion. These relative terms are for convenience of description, do not require that the present disclosure be constructed or operated in a particular orientation, and shall not be construed as causing limitations to the present disclosure.

In the accompanying drawings, wherein the identical or similar reference numerals constantly denote the identical or similar elements or elements having the identical or similar functions. In the drawings, structurally identical components are denoted by the same reference numerals, and structural or functionally similar components are denoted by like reference numerals. Moreover, a size and a thickness of each component shown in the drawings are arbitrarily shown for ease of understanding and description, and the present disclosure does not limit the size and thickness of each component.

When a component is described as “on” another component, the component can be placed directly on the other component; an intermediate component can also exist, the component is placed on the intermediate component, and the intermediate component is placed on another component. When a component is described as “installed to” or “connected to” another component, it can be understood as directly “installed to” or “connected to”, or a component is “mounted to” or “connected to” another component through an intermediate component.

As shown in FIG. 2, an embodiment of the present disclosure provides an organic light-emitting display panel. The organic light-emitting display panel comprises: a substrate 1, a first electrode 2, a light-shielding layer 3, a buffer layer 4, a second electrode 5, a source/drain electrode layer 6, a dielectric layer 7, a passivation layer 8, a color resist layer 9, a planar layer 10, an anode layer 11, and a pixel definition layer 12.

The substrate 1 comprises a thin film transistor 100 and a light-emitting area 200. In current technology, a display panel comprises a thin film transistor area 11, a light-emitting area 12, and a capacitor area 13. The embodiment disposes capacitors which are originally in the original capacitor area in the light-emitting area, and removes the original capacitor area to reduce sizes of pixel areas, thereby improving resolution of display panels.

The first electrode 2 is disposed on an upper surface of the substrate 1. Material of the first electrode 2 comprises at least one of transparent indium-doped zinc oxide (IZO), aluminum-doped zinc oxide (AZO), or aluminum-indium-doped zinc oxide (IAZO). A thickness of the first electrode 2 ranges from 300 Å to 2000 Å.

The doped film has a great conductivity and a reduced resistivity. The transparent indium-doped zinc oxide (IZO), aluminum-doped zinc oxide (AZO), and aluminum-indium-doped zinc oxide (IAZO) have better stability than indium tin oxide (ITO) in hydrogen plasma, and meanwhile have similar optoelectronic properties compared to ITO. Preparation of aluminum-doped zinc oxide (AZO) is convenient, and the element resource is richer than indium and non-toxic, gradually becoming the best substitute for ITO films. The material in the embodiment is soft, and storage time after etching is short, so that the material residue during etching can be prevented, and etching effect is improved.

The light-shielding layer 3 is disposed on an upper surface of the first electrode 2 of the thin film transistor 100. Material of the light-shielding layer 3 comprises at least one of molybdenum (Mo), aluminum (Al), copper (Cu), titanium (Ti), or alloys thereof. A thickness of the light-shielding layer 3 ranges from 500 Å to 10000 Å. The light-shielding layer 3 is used to block light and ensure that property of the first electrode underneath is not changed.

The buffer layer 4 is disposed on upper surfaces of the substrate 1, the first electrode 2, and the light-shielding layer 3. Material of the buffer layer 4 comprises silicon oxide (SiO), silicon nitride (SiN), or a mixed material of the two. A thickness of the buffer layer 4 ranges from 500 Å to 6000 Å. The buffer layer 4 is used for buffering.

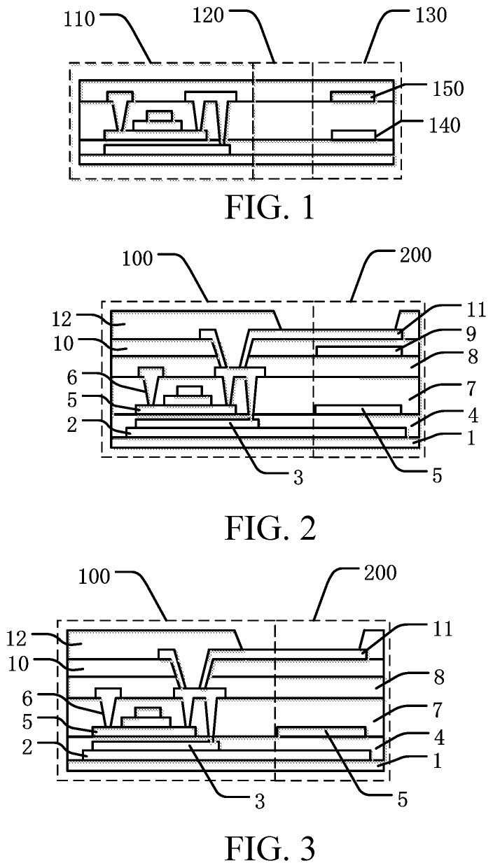

The second electrode 5 is disposed on an upper surface of the buffer layer 4. A part of the second electrode is disposed in the thin film transistor 100, and the other part of the second electrode is disposed in the light-emitting area 200. The first electrode 2 and the second electrode 5 form a transparent capacitor in the light-emitting area 12. The second electrode 5 has a same material and a same position (as shown in FIG. 1) as a capacitor layer in current technology. The material of the second electrode 5 comprises at least one of indium gallium zinc oxide (IGZO), indium zinc titanium oxide (IZTO), or indium gallium zinc titanium oxide (IGZTO).

The source/drain electrode layer 6 is disposed on an upper surface of the second electrode of the thin film transistor 100. Wherein a gate insulating layer is disposed on the upper surface of the second electrode 5. Material of the gate insulating layer is silicon oxide (SiOx), silicon nitride (SiNx), or a multi-layered structure film. A thickness of the gate insulating layer ranges from 1000 Å to 3000 Å. A gate electrode layer is disposed on an upper surface of the gate insulating layer. Material of the gate electrode layer comprises at least one of molybdenum (Mo), aluminum (Al), copper (Cu), titanium (Ti), or alloys thereof. A thickness of the gate electrode layer ranges from 2000 Å to 10000 Å.

The dielectric layer 7 is disposed on upper surfaces of the buffer layer 4, the source/drain electrode layer 6, and the second electrode 5. Material of the dielectric layer 7 is SiOx, SiNx, or a multi-layered structure film, and a thickness of the dielectric layer 7 ranges from 2000 Å to 10000 Å. The dielectric layer 7 is provided with a first through-hole penetrating through the dielectric layer 7, and the first through-hole is disposed opposite to an active layer. The first through-hole provides a channel for the subsequent source/drain electrode.

A source electrode of the source/drain electrode layer 6 is disposed in one first through-hole with one end electrically connected to the second electrode 5 and the other end connected to the light-shielding layer; a drain electrode of the source/drain electrode layer 6 is disposed in another first through-hole and electrically connected to the second electrode 5. Material of the source/drain electrode comprises at least one of molybdenum (Mo), aluminum (Al), copper (Cu), titanium (Ti), or alloys thereof. A thickness of the source/drain electrode layer ranges from 2000 Å to 8000 Å.

The passivation layer 8 is disposed on upper surfaces of the source/drain electrode layer 6 and the dielectric layer 7. Material of the passivation layer 8 comprises silicon oxide (SiOx), silicon nitride (SiNx), or a multi-layered structure film. A thickness of the passivation layer 8 ranges from 1000 Å to 5000 Å.

The color resist layer 9 is disposed on an upper surface of the passivation layer of the light-emitting area 200. The color resist layer 9 is R/G/B color resists. According to requirements, the color resist layer 9 can be removed (as shown in FIG. 3) without affecting display effect of the display panel.

The planar layer 10 is disposed on upper surfaces of the passivation layer 8 and the color resist layer 9, or the upper surface of the passivation layer 8. The planar layer 10 is provided with a second through-hole. The second through-hole penetrates the planar layer 10 and part of the passivation layer, and doesn't cover the source electrode of the source/drain electrode layer 6.

The anode layer 11 is disposed on an inner side wall of the second through-hole and extends to an upper surface of the planar layer 10 of the light-emitting area. The material of the anode layer 11 is indium tin oxide (ITO).

The pixel definition layer 12 is disposed on upper surfaces of the planar layer 10 and the anode layer 11 to define the size of the light-emitting area. A third through-hole is disposed on the pixel definition layer 12, and the third through-hole is disposed opposite to a second electrode 5 to prevent luminescent materials.

The technical effect of the organic light-emitting display panel in the embodiment is: removing the original first capacitor layer in the pixel area and disposing a new first electrode on a bottom of the display panel. Material of the first electrode comprises at least one of transparent indium-doped zinc oxide (IZO), aluminum-doped zinc oxide (AZO), or aluminum-indium-doped zinc oxide (IAZO). The above oxides have good volatility that prevents material residue during etching and improves etching effect. The present disclosure disposes capacitors which are originally in the original capacitor area in the light-emitting area, and removes the original capacitor area to reduce sizes of pixel areas, thereby improving resolution of display panels.

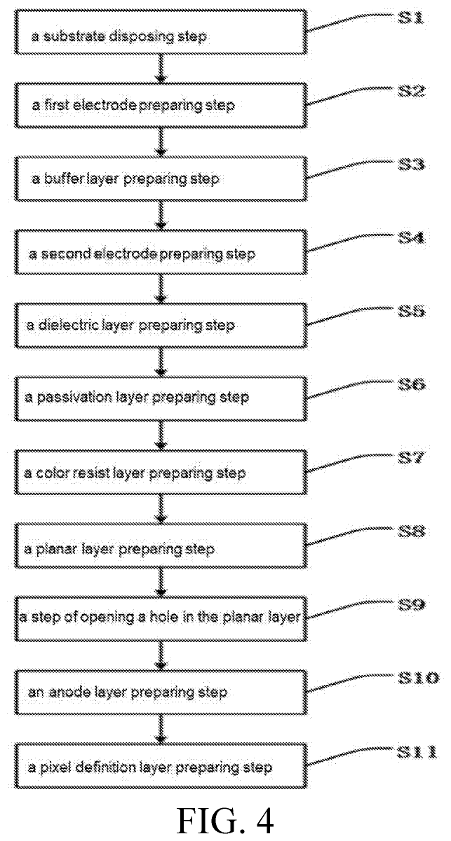

As shown in FIG. 4, the embodiment of the present disclosure further provides a manufacturing method of an organic light-emitting display panel. The method comprises following steps S1 to S6:

S1: a substrate disposing step of disposing a substrate. The substrate comprises a thin film transistor and a light-emitting area. The embodiment disposes capacitors which are originally in the original capacitor area in the light-emitting area, and removes the original capacitor area to reduce sizes of pixel areas, thereby improving resolution of display panels.

S2: a first electrode preparing step of preparing a first electrode and a light-shielding layer on an upper surface of the substrate. The first capacitor layer in current technology is disposed on a bottom of the display panel to form a new first electrode, and material of the first electrode is changed from original indium tin oxide to at least one selected from the group consisting of transparent indium-doped zinc oxide (IZO), aluminum-doped zinc oxide (AZO), and aluminum-indium-doped zinc oxide (IAZO). Its storage time after etching is short, so that the material residue during etching can be prevented, and etching effect is improved.

S3: a buffer layer preparing step of preparing a buffer layer on upper surfaces of the substrate, the first electrode, and the light-shielding layer. Material of the buffer layer comprises silicon oxide (SiO), silicon nitride (SiN), or a mixed material of the two. A thickness of the buffer layer ranges from 500 Å to 6000 Å.

S4: a second electrode preparing step of preparing a thin film transistor and a second electrode on an upper surface of the buffer layer, wherein the thin film transistor is disposed on the second electrode, and the second electrode has a same material and position as current technology, making the first electrode and the second electrode form a transparent capacitor in the light-emitting area.

S5: a dielectric layer preparing step of preparing a dielectric layer on the second electrode and the thin film transistor. Material of the dielectric layer is silicon oxide (SiOx), silicon nitride (SiNx), or a multi-layered structure film. A thickness of the dielectric layer ranges from 2000 Å to 10000 Å. A metal layer is deposited on an upper surface of the dielectric layer, then a source electrode pattern and a drain electrode pattern are etched, making one end of the source electrode penetrate the dielectric layer and connecting to the second electrode, and making the other end penetrate the dielectric layer and connecting to the light-shielding layer. The drain electrode penetrates the dielectric layer and is connected to the second electrode.

S6: a passivation layer preparing step of preparing a passivation layer on an upper surface of the dielectric layer. Material of the passivation layer comprises silicon oxide (SiOx), silicon nitride (SiNx), or a multi-layered structure film. A thickness of the passivation layer ranges from 1000 Å to 5000 Å.

S7: a color resist layer preparing step of preparing a color resist layer on an upper surface of the passivation layer of the light-emitting area. The color resist layer is R/G/B color resists, and is used to display colors. In other embodiments, the color resist layer preparing step can be omitted without affecting display effect of the display panel.

S8: a planar layer preparing step of preparing a planar layer on upper surfaces of the passivation layer and the color resist layer.

S9: a step of opening a hole in the planar layer. Drilling down on the planar layer, penetrating through the planar layer and part of the passivation layer to form a through-hole. The through hole passes through the planar layer and part of the passivation layer to expose a source electrode of the thin film transistor to facilitate connection between subsequent thin film layer and the thin film transistor.

S10: an anode layer preparing step of preparing an anode layer on an inner side wall of the through-hole, and the anode layer extending to the planar layer of the light-emitting area. Material of the anode layer is indium tin oxide (ITO).

S11: a pixel definition layer preparing step of preparing a pixel definition layer on upper surfaces of the planar layer and the anode layer of the thin film transistor.

The prepared thin film layer is the same as the transparent capacitor layer in current technology, so it is only briefly illustrated herein.

The prepared organic light-emitting display panel in the embodiment is: removing the original first capacitor layer in the pixel area and disposing a new first electrode on a bottom of the display panel. Material of the first electrode comprises at least one of transparent indium-doped zinc oxide (IZO), aluminum-doped zinc oxide (AZO), or aluminum-indium-doped zinc oxide (IAZO). The above oxides have good volatility that prevents material residue during etching, thereby improving etching effect. The present disclosure disposes capacitors which are originally in the original capacitor area in the light-emitting area, and removes the original capacitor area to reduce sizes of pixel areas, thereby improving resolution of display panels.

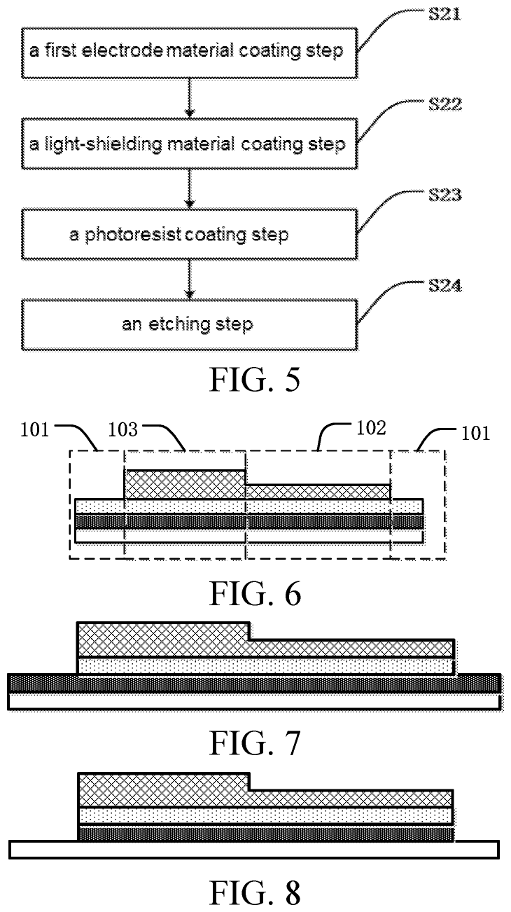

As shown in FIG. 5, the above S2 of the first electrode preparing step comprises steps S21 to S24.

S21: a first electrode material coating step of coating a first electrode material on the upper surface of the substrate. The material of the first electrode comprises at least one of transparent indium-doped zinc oxide (IZO), aluminum-doped zinc oxide (AZO), or aluminum-indium-doped zinc oxide (IAZO). A thickness of the first electrode ranges from 300 Å to 2000 Å. The material of the first electrode is soft, and its storage time after etching is short, so it's not easy to leave residue.

S22: a light-shielding material coating step of coating a light-shielding material on an upper surface of the first electrode material. Material of the light-shielding material comprises at least one of molybdenum (Mo), aluminum (Al), copper (Cu), titanium (Ti), or alloys thereof. A thickness of the light-shielding material ranges from 500 Å to 10000 Å.

S23: a photoresist coating step of coating a photoresist on an upper surface of the light-shielding material (as shown in FIG. 6) in a photolithography process (half-tone process). The photoresist divides the display panel into a fully exposed area 101, an incompletely exposed area 102, and a completely unexposed area 103 to facilitate subsequent etching and exposure.

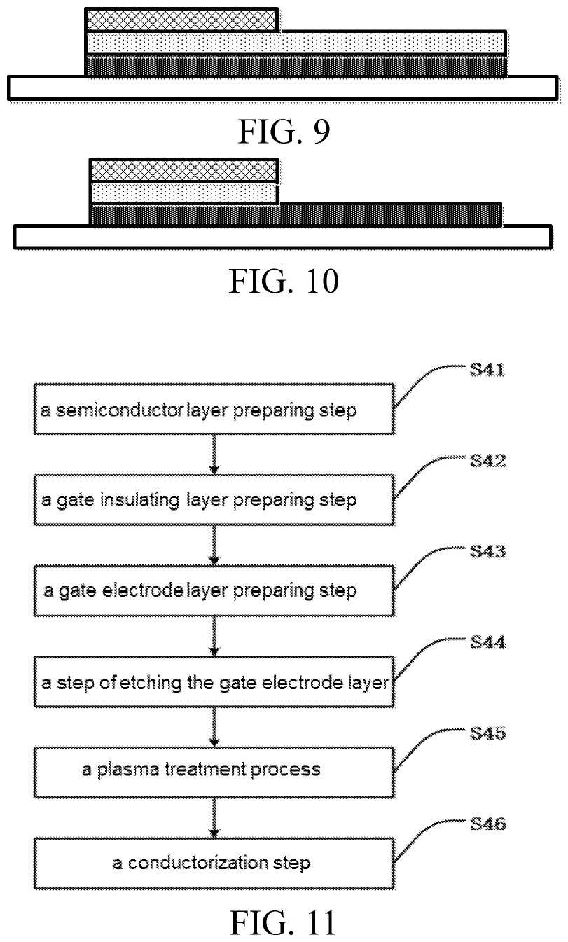

S24: an etching step of etching to form the first electrode and the light-shielding layer. As shown from FIG. 7 to FIG. 10, the etching step specifically comprises: performing a first etching of the light-shielding layer in the fully exposed area 101 (as shown in FIG. 7), and using oxalic acid to wet etch the first electrode in the fully exposed area 101 (as shown in FIG. 8). Performing an ashing treatment on the photoresist, and making the photoresist etched in the incompletely exposed area 102 (as shown in FIG. 9). Performing a second etching of the light-shielding layer at last, which etches the light-shielding layer in the incompletely exposed area 102 and only the light-shielding layer in the completely unexposed area 103 is left (as shown in FIG. 10), and finishing preparation of the light-shielding layer and the first electrode.

Because the prepared first electrode is soft and its storage time after etching is short, it is not easy to leave etching traces and can thus improve etching effect.

As shown in FIG. 11, the second electrode preparing step comprises steps S41 to S46.

S41: a semiconductor layer preparing step of coating a layer of metal oxide semiconductor material on an upper surface of the buffer layer to form the semiconductor layer, and etching to form a semiconductor pattern. Material of the metal oxide semiconductor material comprises at least one of indium gallium zinc oxide (IGZO), indium zinc titanium oxide (IZTO), or indium gallium zinc titanium oxide (IGZTO). A thickness of the semiconductor layer ranges from 100 Å to 1000 Å.

S42: a gate insulating layer preparing step of depositing a layer of metal on an upper surface of the semiconductor pattern to prepare a gate insulating layer. Material of the gate insulating layer is silicon oxide (SiOx), silicon nitride (SiNx), or a multi-layered structure film. A thickness of the gate insulating layer ranges from 1000 Å to 3000 Å.

S43: a gate electrode layer preparing step of preparing a gate electrode layer on an upper surface of the gate insulating layer. Material of the gate electrode layer comprises at least one of molybdenum (Mo), aluminum (Al), copper (Cu), titanium (Ti), or alloys thereof. A thickness of the gate electrode layer ranges from 2000 Å to 10000 Å.

S44: a step of etching the gate electrode layer of using photolithography process to etch a pattern of the gate electrode layer first, then etching a pattern of the gate insulating layer, and making the pattern of the gate insulating layer disposed opposite to the pattern of the gate electrode layer.

S45: a plasma treatment process of performing a plasma treatment on the entire upper surface of the substrate that makes the semiconductor pattern not covered by the gate insulating layer have a significantly reduced resistance and form a N+ conductor layer, and makes the semiconductor pattern covered by the gate insulating layer form thin film transistor channels and keep its semiconductor property.

S46: a conductorization step of conductorizing the conductor layer on the light-emitting area to form the second electrode.

The prepared second electrode is the same as the transparent capacitor layer in current technology, so it is only briefly illustrated herein.

The technical effect of the manufacturing method of the organic light-emitting display panel in the embodiment is: removing the original first capacitor layer in the pixel area and disposing a new first electrode on a bottom of the display panel. Material of the first electrode comprises at least one of transparent indium-doped zinc oxide (IZO), aluminum-doped zinc oxide (AZO), or aluminum-indium-doped zinc oxide (IAZO). The above oxides have good volatility that prevents material residue during etching and improves etching effect. The present disclosure disposes capacitors which are originally in the original capacitor area in the light-emitting area, and removes the original capacitor area to reduce sizes of pixel areas, thereby improving resolution of display panels.

The present disclosure has been described with a preferred embodiment thereof. The preferred embodiment is not intended to limit the present disclosure, and it is understood that many changes and modifications to the described embodiment can be carried out without departing from the scope and the spirit of the disclosure that is intended to be limited only by the appended claims.

What is claimed is:

1. An organic light-emitting display panel, comprising:
a substrate comprising a thin film transistor and a light-emitting area;
a first electrode disposed on the substrate, wherein the first electrode is a transparent electrode;
a light-shielding layer disposed on the first electrode;
a buffer layer disposed on the light-shielding layer; and
a second electrode disposed on the buffer layer, wherein the second electrode is a transparent electrode;
wherein the first electrode and the second electrode form a transparent capacitor in the light-emitting area.

2. The organic light-emitting display panel according to claim 1, wherein
material of the first electrode comprises at least one of transparent indium-doped zinc oxide, aluminum-doped zinc oxide, or
aluminum-indium-doped zinc oxide.

3. The organic light-emitting display panel according to claim 1, wherein
material of the second electrode comprises at least one of indium gallium zinc oxide, indium zinc titanium oxide, or indium gallium zinc titanium oxide.

4. The organic light-emitting display panel according to claim 1, wherein
the first electrode extends from below the second electrode of the light-emitting area to below the light-shielding layer.

5. The organic light-emitting display panel according to claim 1, wherein
the thin film transistor comprises:
an active layer disposed on the buffer layer;
a gate insulating layer disposed on the active layer;
a gate electrode disposed on the gate insulating layer;
a dielectric layer disposed on the gate electrode;
a first through-hole penetrating through the dielectric layer; and
a source/drain electrode layer disposed on the dielectric layer and electrically connected to the active layer by the first through-hole.

6. The organic light-emitting display panel according to claim 4, comprising:
a passivation layer disposed on the dielectric layer;
a planar layer disposed on the passivation layer;
a second through-hole recessed in the planar layer and part of the passivation layer;
an anode layer disposed on an inner side wall of the second through-hole and extending to the planar layer of the light-emitting area;
a pixel definition layer disposed on the planar layer and the anode layer; and
a third through-hole penetrating through the pixel definition layer.

7. The organic light-emitting display panel according to claim 6, comprising:
a color resist layer disposed on the passivation layer of the light-emitting area and opposite to the third through-hole;
wherein the planar layer is disposed on the passivation layer and the color resist layer.

8. The organic light-emitting display panel according to claim 6, wherein
the second electrode is disposed opposite to the third through-hole.

9. A manufacturing method of an organic light-emitting display panel, comprising following steps:
providing a substrate;
preparing a first electrode and a light-shielding layer on an upper surface of the substrate;
preparing a buffer layer on upper surfaces of the substrate, the first electrode, and the light-shielding layer; and
preparing a thin film transistor and a second electrode on an upper surface of the buffer layer, wherein the thin film transistor is disposed on the second electrode making the first electrode and the second electrode form a transparent capacitor in the light-emitting area.

10. The manufacturing method of the organic light-emitting display panel according to claim 9, wherein
the preparing step of the first electrode comprises:
coating a first electrode material on the upper surface of the substrate;
coating a light-shielding material on an upper surface of the first electrode material;
coating a layer of photoresist on an upper surface of the light-shielding material; and
etching to form the first electrode and the light-shielding layer;
the preparing step of the second electrode comprises:
preparing a semiconductor layer on the upper surface of the buffer layer and etching to form a semiconductor pattern;
preparing a gate insulating layer on an upper surface of the semiconductor pattern;
preparing a gate electrode layer on an upper surface of the gate insulating layer;
etching a pattern of the gate electrode layer first, then etching a pattern of the gate insulating layer, and making the pattern of the gate insulating layer disposed opposite to the pattern of the gate electrode layer;
performing a plasma treatment on the entire upper surface of the substrate that makes the semiconductor pattern not covered by the gate insulating layer form a conductor layer and the semiconductor pattern covered by the gate insulating layer form thin film transistor channels; and
conductorizing the conductor layer on the light-emitting area to form the second electrode.
